(19) United States
(12) Patent Application Publication
(10) Pub. No.: US 2012/0299049 A1
(43) Pub. Date: Nov. 29, 2012

(54) Optoelectronic Semiconductor Chip and Method for Adapting a Contact Structure for Electrically Contacting an Optoelectronic Semiconductor Chip

(75) Inventors: Patrick Rode, Regensburg (DE); Lutz Höppel, Alteglofsheim (DE); Norwin von Malm, Nittendorf-Thumhausen (DE); Matthias Sabathil, Regensburg (DE); Jürgen Moosburger, Regensburg (DE)

(73) Assignee: OSRAM OPTO SEMICONDUCTORS GMBH, Regensburg (DE)

(21) Appl. No.: 13/497,733

(22) PCT Filed: Sep. 10, 2010
(86) PCT No.: PCT/DE10/01077

§ 371 Date: May 8, 2012

(30) Foreign Application Priority Data
Sep. 30, 2009 (DE) 10 2009 047 889.2

(51) Int. Cl. H01L 33/48; H01R 43/16

(52) U.S. Cl. 257/99; 29/874; 257/E33.066

(57) ABSTRACT

An optoelectronic semiconductor chip has a first semiconductor functional region with a first terminal and a second terminal. A contact structure electrically contacts the optoelectronic semiconductor chip. The contact structure is connected electrically conductively to the first semiconductor functional region. The contact structure has a disconnectable conductor structure. An operating current path is established via the first terminal of the first semiconductor functional region and the second terminal if the conductor structure is not disconnected. This path is interrupted if the conductor structure is disconnected. Alternatively, an operating current path is established via the first terminal of the first semiconductor functional region and the second terminal if the conductor structure is disconnected. The conductor structure connects the first terminal to the second terminal and short circuits the first semiconductor functional region if the conductor structure is not disconnected.

This patent application is a national phase filing under section 371 of PCT/DE2010/001077, filed Sep. 10, 2010, which claims the priority of German patent application 10 2009 047 889.2, filed Sep. 30, 2009, each of which is incorporated herein by reference in its entirety.

### TECHNICAL FIELD

The invention relates to an optoelectronic semiconductor chip with a semiconductor functional region and a contact structure for electrically contacting the optoelectronic semiconductor chip and to a method for adapting a contact structure for electrically contacting an optoelectronic semiconductor chip.

### BACKGROUND

“Fuses” are known from Si technology. Fuses are conductor track structures which, like conventional fuses, are blown by a purposefully elevated current flow, i.e., are transferred into an isolating state. This purposeful blowing is also known as “programming.” In this way, interconnections may subsequently be individually modified. Such fuses serve, for example, to deactivate circuit arrangements or regions thereof, if, for example, the prevailing current flow exceeds a predetermined value. Fuses are conventionally conductor tracks leading to transistors, which may be adapted with regard to function by means of the programmable fuses.

It is known from GB 2381381 and DE 10 2004 025 684 to modify a contact structure for an optoelectronic semiconductor chip with a plurality of semiconductor functional regions. The contact structure may be isolated from a defective semiconductor functional region, such that the latter is permanently deactivated. In this way, functionality of the optoelectronic chip is thus feasible even in the case of defects in individual semiconductor functional regions.

### SUMMARY

It is desirable to allow adaptation of a contact structure for an optoelectronic semiconductor chip to predetermined operating parameters, such as, for example, a predetermined supply voltage.

The optoelectronic semiconductor chip comprises a first semiconductor functional region with a first terminal and a second terminal and a contact structure for electrically contacting the optoelectronic semiconductor chip, which contact structure is connected electrically conductively to the first semiconductor functional region. The contact structure comprises a disconnectable conductor structure, wherein an operating current path is established across the first terminal of the first semiconductor functional region and the second terminal if the conductor structure is not disconnected, which path is interrupted if the conductor structure is disconnected. Alternatively, an operating current path is established across the first terminal of the first semiconductor functional region and the second terminal if the conductor structure is disconnected, wherein the conductor structure connects the first terminal to the second terminal and short circuits the first semiconductor functional region if the conductor structure is not disconnected.

In case the conductor structure connects the first terminal to the second terminal if the conductor structure is not disconnected, the first semiconductor functional region is short-circuited, or deactivated. “Short-circuited” is understood to mean that no potential difference, or only an infinitesimal potential difference is present at the semiconductor functional regions, even when the supply voltage is applied to the semiconductor chip. The semiconductor functional region is not operational.

By disconnecting the conductor structure the short-circuited first semiconductor functional region may be changed over into a state in which it is operational. The short circuit is eliminated. On application of the supply voltage to the semiconductor chip, a sufficient voltage drop advantageously occurs across the semiconductor functional region to operate the latter, such that, for example, electromagnetic radiation is emitted.

The semiconductor functional region may be a modular element within a component. Advantageously, however, the semiconductor chip comprises the semiconductor functional region as part of an integrated circuit, as may be produced in the wafer composite. The wafer composite comprises a semiconductor layer sequence arranged on the carrier layer, which sequence is provided to form at least some of the semiconductor functional regions, after which the semiconductor layer sequence is patterned in such a way that a plurality of semiconductor functional regions arise. The semiconductor functional region may comprise one or more radiation-generating sub-regions or units. These may, for example, be series-connected. Parallel connection or a combination of series and parallel connection is also feasible.

The contact structure provides conductive connections to the semiconductor functional region and makes it possible to apply to the semiconductor functional region a voltage necessary for operation of the latter, provided it is operational. A potential may be applied to a terminal of the semiconductor functional region. By applying an operating voltage across the terminals of the semiconductor functional region, the latter may be operated. The terminal may be a region of the semiconductor functional region, to which the contact structure is guided to the semiconductor functional region.

The first semiconductor functional region may be short-circuited, i.e., bridged, by a parallel-connected conductor structure. The short circuit may be eliminated by disconnection of the conductor structure. “Disconnection” involves the formation of an isolation gap within the conductor structure, such that an electrically conductive connection is changed over to an isolating state.

The conductor structure comprises disconnectable regions, which differ, for example, in terms of their design from the remaining contact structure, in order to simplify recognition of these regions and prevent undesired disconnection of contact structures necessary for operation. The provision of disconnectable regions of the conductor structure may also be regarded as a type of fuse technology, adapted for and applied to segmented multi-pixel LEDs. The disconnectable conductor structure may be in a disconnected state or in a non-disconnected state. Advantageously it may be changed over just once from the non-disconnected into the disconnected state, this being non-reversible.

Such an optoelectronic semiconductor chip may, for example, be adapted to a predetermined supply voltage, by modifying the contact structure by disconnection of the conductor structure.

Advantageously the semiconductor functional region comprises an active zone, which is intended for generating radiation or receiving radiation. Such semiconductor functional regions, which emit electromagnetic radiation, in particular visible, ultraviolet and/or infrared light, are provided in an LED chip. In an LED chip an emitting semiconductor functional region is also known as a pixel. An LED chip may comprise a plurality of pixels.

Connectable pixels may be connected downstream of an arrangement with a plurality of pixels. Such an arrangement may be produced, for example, by pixelation of a plurality of LED semiconductor functional regions. The pixels thereof may be series-connected. Such arrangements are also known as high volt LEDs.

In one exemplary embodiment the conductor structure is connected in parallel to the first semiconductor functional region. If the conductor structure is not disconnected, it is short-circuited. If the conductor structure is disconnected, the short circuit is eliminated and the first semiconductor functional region is operational.

One configuration provides a second semiconductor functional region with a third and a fourth terminal. A connection region of the contact structure connects the second and third terminals. The conductor structure comprises a first branch extending between the first terminal and the connection region, which first branch is disconnectable or disconnected, and a second branch extending between the connection region and the fourth terminal, which second branch is disconnectable or disconnected. Branches extending to the second or third terminals also comprise branches extending to the connection region, since the latter is connected with the terminals.

A non-disconnected branch is an electrically conductive connection, for example, between terminals and/or a contact structure region. The branch may comprise a plurality of electrically conductive, interconnected regions of the contact structure or of the conductor structure. A disconnected branch has a region in which an isolation structure prevents electrical conductivity between the terminals and/or the contact structure region.

In the above described configuration, it is not just one semiconductor functional region which may be connected by disconnection of one of the branches, i.e., transferred into an operational state, but instead both semiconductor functional regions, which increases the chip adaptation options. The above-described arrangement is cascadable, such that more than two semiconductor functional regions may be connected.

In one configuration, the first and second branches have a common region, which is separable or separated. This comb-like structure simplifies the design.

One configuration provides a second semiconductor functional region with a third and fourth terminal. The conductor structure comprises a first branch extending between the first and the third terminal, which first branch is disconnectable or disconnected, and a second branch extending between the second and the fourth terminal, which second branch is disconnectable or disconnected, and a third branch extending between the second and the third terminal, which third branch is disconnectable or disconnected. In this arrangement individual or both semiconductor functional regions may be connected. When connecting the two semiconductor functional regions, they may be connected in series or in parallel. If none of the branches is disconnected, both semiconductor functional regions are deactivated. If only the third branch is disconnected, the semiconductor functional regions are connected in parallel. If only the first and second branches are disconnected, the semiconductor functional regions are connected in series. If only the first or second branch is disconnected, only one of the semiconductor functional regions is connected.

In one configuration, in addition to the connectable semiconductor functional region a plurality of series-connected semiconductor functional regions are also provided, which are already operational before disconnection of the conductor structure. “Operational” means that, on application of a supply voltage to the semiconductor chip, an operating voltage drop occurs, which is advantageously sufficient for operation of the semiconductor functional regions.

A method is provided for adapting a contact structure for electrically contacting the optoelectronic semiconductor chip. The optoelectronic semiconductor chip comprises a first semiconductor functional region with a first terminal and a second terminal, and a contact structure for electrically contacting the optoelectronic semiconductor chip, which contact structure is connected electrically conductively to the first semiconductor functional region, the contact structure comprising a disconnectable conductor structure. The method comprises disconnecting an operating current path, which is established across the first terminal of the semiconductor functional region and the second terminal, such that the operating current path is interrupted. Alternatively, the method comprises disconnecting the conductor structure, which connects the first terminal with the second terminal and short-circuits the semiconductor functional region, such that when the conductor structure is disconnected an operating current path is established across the first terminal of the semiconductor functional region and the second terminal.

The method may be used for a semiconductor chip in which a second semiconductor functional region, which has a third and a fourth terminal, is also provided. A connection region of the contact structure connects the second and third terminals. The conductor structure comprises a first branch electrically connecting the first terminal and the connection region and a second branch electrically connecting the connection region and the fourth terminal. The first branch may be disconnected, such that the first semiconductor functional region is connected. Alternatively, the second branch may be disconnected, such that the second semiconductor functional region is connected, or the first and the second branches may be disconnected, such that both semiconductor functional regions are connected in series.

The adaptation method may be used for a contact structure for a semiconductor chip in which a second semiconductor functional region, which has a third and a fourth terminal, is also provided, wherein the conductor structure comprises a first branch electrically connecting the first and the third terminals and a second branch connecting the second and the fourth terminals and a third branch connecting the second and the third terminals. If only the third branch is disconnected, the semiconductor functional regions are connected in parallel. If only the first branch is disconnected, the first semiconductor functional region is transferred into an operational state. If only the second branch is disconnected, the second semiconductor functional region is transferred into an operational state. If only the first and second branches are disconnected, both semiconductor functional regions are connected in series.

With the method, a total forward voltage of the semiconductor functional regions may be detected and the conductor structure disconnected in such a way that the difference between the total forward voltage and a predetermined supply voltage is reduced. Through the purposeful connection of semiconductor functional regions it is possible to set the forward voltage of the semiconductor chip and adapt it to the predetermined supply voltage.

During fabrication, the forward voltage of the semiconductor functional regions may be subject to processing variations, such that it may be difficult to set a predetermined total forward voltage. The purposeful connection of semiconductor functional regions allows direct setting of the target voltage. The upstream connection of resistors, known from conventional circuitry, which was associated with the conversion of electrical power into heat and reduced the efficiency of the component in order to regulate the target voltage, is not required. This allows more compact construction.

The provision of connectable pixels, which may be connected or disconnected, enables direct setting of the forward voltage of the high volt LEDs.

Disconnection of the conductor structure may proceed by laser ablation of a part thereof. Disconnection may proceed by a lithographic method, for example, by direct write lithography, in which the conductor structures are etched away in places. Disconnection by a current flow of a predetermined minimum current intensity may, in the event of too high a current flow, be associated with damage to the pixels. In this case, a current flow which is elevated in comparison with normal operation should purposefully blow the disconnectable conductor structure regions.

Disconnection may take place directly in the wafer composite on the chip. Other structuring methods are feasible.

### BRIEF DESCRIPTION OF THE DRAWINGS

Further features, configurations, advantages and convenient aspects are revealed by the following description of the following exemplary embodiments in conjunction with the figures.

FIG. 1 is a schematic representation of an exemplary embodiment of the arrangement of a contact structure for an optoelectronic semiconductor chip with a plurality of semiconductor functional regions;

FIG. 2 is a schematic representation of a further exemplary embodiment of the arrangement of a contact structure for an optoelectronic semiconductor chip with a plurality of semiconductor functional regions;

FIG. 3 is a schematic representation of a further exemplary embodiment of the arrangement of a contact structure for an optoelectronic semiconductor chip with a plurality of semiconductor functional regions;

FIG. 4 is a schematic representation of a further exemplary embodiment of the arrangement of a contact structure for an optoelectronic semiconductor chip with a plurality of semiconductor functional regions; and

FIGS. 5A to 5C are schematic representations of fabrication of the contact structure in FIG. 4.

### DETAILED DESCRIPTION OF ILLUSTRATIVE EMBODIMENTS

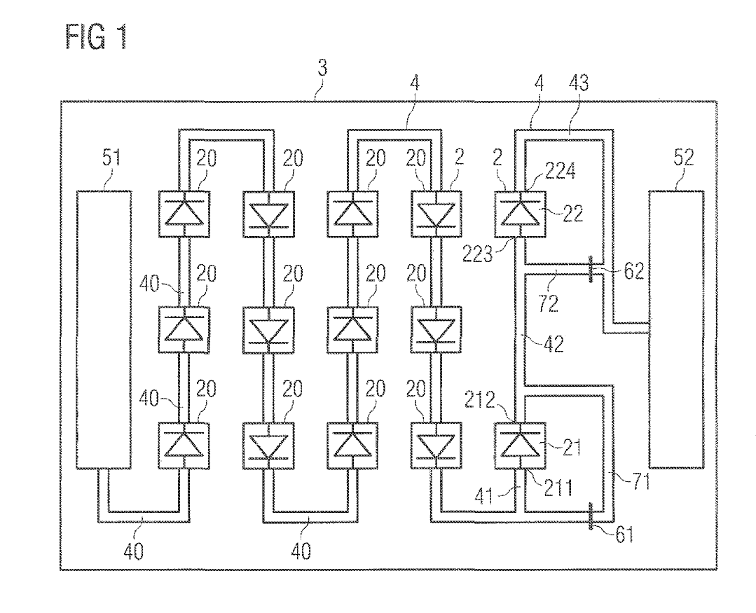

FIG. 1 is a schematic representation of an exemplary embodiment of the arrangement of a contact structure for an optoelectronic semiconductor chip with a plurality of semiconductor functional regions.

In one exemplary embodiment, the semiconductor chip is an integrated circuit with a plurality of semiconductor functional regions 2, which are arranged on a common carrier 3. The semiconductor functional regions 2 are arranged on the carrier 3 such that they are aligned into a lattice-like grid.

When fabricating such a semiconductor chip the semiconductor functional regions 2 may be provided on a common carrier in the wafer composite. The semiconductor layer sequence, in particular the active zone, is preferably based on a III-V semiconductor material, for example, InₓGa_{y}Al_{1-x-y}P, and is designed for LED chips.

Alternatively, the semiconductor chip comprises modular elements with semiconductor functional regions, which are arranged on a carrier and are optionally at least partially surrounded by a housing.

The semiconductor functional regions 2 have an active layer, which emits electromagnetic radiation, preferably light in the ultraviolet, visible and/or infrared ranges. These semiconductor functional regions 2 serve as LEDS or pixels.

A contact structure 4 is provided for electrically contacting the optoelectronic semiconductor chip. The contact structure comprises a first contact 51 and a second contact 52, to which a supply voltage for the semiconductor chip may be applied, with which the semiconductor functional regions 2 are supplied on operation of the semiconductor chips.

The semiconductor functional regions 2 comprise a group of operational semiconductor functional regions 20 and a first and a second connectable semiconductor functional region 21, 22. On application of the supply voltage to the contacts 51, 52, a voltage drop, preferably a sufficient voltage drop for operating the semiconductor functional regions, occurs across the operational semiconductor functional regions 20, such that light is emitted from these semiconductor functional regions 20. In an initial state, before any modifications have been made to the contact structure 4, no voltage drop occurs over the connectable semiconductor functional regions 21, 22 on application of a supply voltage to the contacts 51, 52. The semiconductor functional regions 21, 22 are short-circuited in the initial state, such that they do not emit any radiation.

The contact structure 4 is connected electrically conductively to the operational and connectable semiconductor functional regions 20, 21, 22, 23 and the first and the second contacts 51, 52. It serves in electrically contacting the semiconductor chip, such that the semiconductor functional regions are supplied with voltage. In one exemplary embodiment, the contact structure 4 comprises metallic conductor tracks. In one exemplary embodiment, the contact structure comprises conductive layers, which may extend at different levels of an integrated circuit arrangement.

The operational semiconductor functional regions 20 are series-connected by connection regions 40 of the contact structure. The connection regions 40 extend in this exemplary embodiment in a meandering manner between the columns of operational semiconductor functional regions 20. The first and second connectable semiconductor functional regions 21, 22 are connected in series to the operational semiconductor functional regions 20. The first connectable semiconductor functional region 21 has a first and a second terminal 211, 212. A third and a fourth terminal 223, 224 are provided on the second connectable semiconductor functional region 22. In this exemplary embodiment a first region 41 of the contact structure connects the series-connected, operational semiconductor functional regions 20 with the first terminal 211 of the first connectable semiconductor functional region 21. A second region 42 the contact structure connects the second terminal 212 of the first connectable semiconductor functional region 21 with the third terminal 223 on the second connectable semiconductor functional region 22. A third region 43 of the contact structure connects the fourth terminal 224 on the second connectable semiconductor functional region 22 with the second contact 52.

The contact structure 4 further comprises a conductor structure which in the initial state short-circuits the first and second connectable semiconductor functional regions 21, 22. A first arm 71 connects the first region 41 and the second region 42 of the contact structure, such that an electrically conductive connection is obtained between the first and second terminals 211, 212 of the first connectable semiconductor functional region across a first branch, i.e., the first region 41, the first arm 71 and the second region 42. A second arm 72 connects the second region 42 and the third region 43 of the contact structure, such that between the third and fourth terminals 223, 224 of the second connectable semiconductor functional region 22 an electrically conductive connection is formed via the second branch, i.e., the second region 42, the second arm 72 and the third region 43.

The first and second branches short-circuit the first and second connectable semiconductor functional regions 21, 22, i.e., they are at the same, or virtually the same, potential. On application of a supply voltage to the contacts 51, 52, no or only an infinitesimal voltage drop occurs across the connectable semiconductor functional regions 21, 22. They do not emit any radiation.

The arms 71, 72 are disconnectable and to this end are conventionally readily accessible, for example, located in an upper layer. In one exemplary embodiment the arms 71, 72 are conductor tracks. In one exemplary embodiment they are structured semiconductor layer regions. “Disconnectable” with regard to the conductor structure means that, for example, part of the conductor structure is removed, such that an isolation structure is formed. This may be an isolating gap in the conductor structure. Interrupting the first arm 71 eliminates the short circuit of the first connectable semiconductor functional region 21. Interrupting the second arm 72 eliminates the short circuit of the first connectable semiconductor functional region 21. The corresponding semiconductor functional region 21, 22 is thus transferred into an operational state, such that it emits light on application of a supply voltage. Reference numerals 61, 62 designate possible points of the branches which are disconnectable.

A forward voltage is needed to operate a semiconductor functional region 20, 21, 22. The total forward voltage for operating a series connection of semiconductor functional regions 20 takes the form of the total of the individual forward voltages or, assuming that all the semiconductor functional regions have the same forward voltage, of the product of the number of semiconductor functional regions 20 and the forward voltage. It may, depending on the number of semiconductor functional regions, each of which functions as an LED or pixel, amount, for example, to 12V, 24V or 230V. They are therefore also designated high volt LEDs.

The supply voltage which is applied to the semiconductor chip advantageously corresponds to the total forward voltage or is tailored thereto. Due to processing variations during production, the forward voltages of the semiconductor functional regions may vary. This leads to the total forward voltage deviating from a predetermined voltage, with which the semiconductor chip is to be operated. Due to the processing variations, it is difficult to set the forward voltages of the semiconductor functional regions precisely. Subsequent adaptation in a final fabrication step allows modification of the total forward voltage. Thus the provision of additional pixels, which may be connected or disconnected, allows direct and precise setting of the forward voltage in high volt LEDs.

By disconnecting the first and/or second arms 71, 72 the total forward voltage may be adapted to the predetermined supply voltage, for example, in a final fabrication step. Disconnection of the first or second arms 71, 72 may increase the total forward voltage by the forward voltage of the first or second semiconductor functional region 21, 22. In one exemplary embodiment, the forward voltages of the first and second semiconductor functional regions 21, 22 are different. In one exemplary embodiment, the forward voltages of the first and second semiconductor functional regions 21, 22 are not or are not significantly different.

On disconnection of the first branch, the total forward voltage, which depends in the initial state solely on the operational semiconductor functional regions 20, is increased by the forward voltage of the first connectable semiconductor functional region 21. On disconnection of the second branch, the total forward voltage is increased by the forward voltage of the second connectable semiconductor functional region 22. On disconnection of the first and second branches, the total forward voltage is increased by the forward voltages of the first and second connectable semiconductor functional regions 21, 22.

In order to adapt the total forward voltage of the semiconductor chip, two connectable semiconductor functional regions 21, 22 are provided in the above exemplary embodiment. If these are not activated, the inactive semiconductor functional regions go unused.

Alternatively, the connectable semiconductor functional regions may be used to adapt the brightness of the semiconductor chip. By activating the connectable semiconductor functional regions, the number of semiconductor functional regions which emit radiation is increased, this approach thus enabling brightness control.

Adaptation of the contact structure may proceed during production of the semiconductor chip as the final fabrication step. It is also feasible for adaptation to take place before singulation of the chips in the wafer composite, as an on-wafer solution.

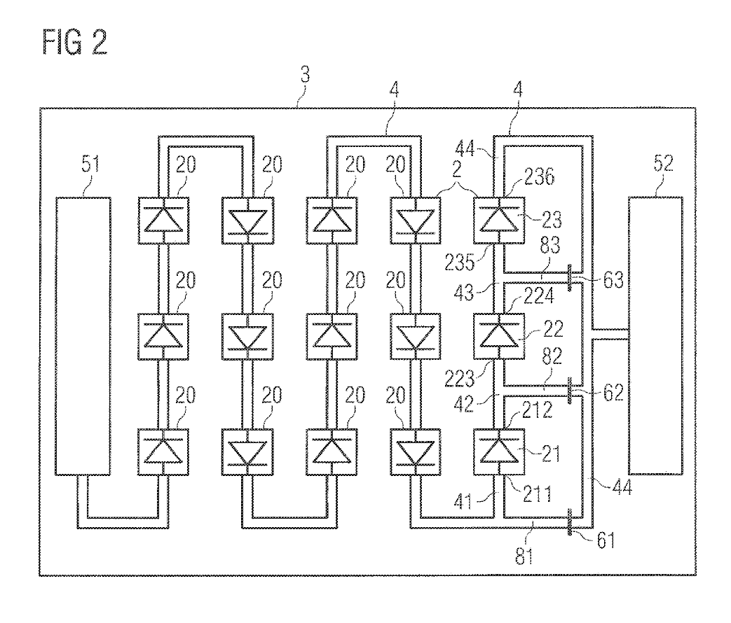

FIG. 2 is a schematic representation of a further exemplary embodiment of the arrangement of a contact structure for an optoelectronic semiconductor chip with a plurality of semiconductor functional regions. Identical reference signs identify identical features or features with the same or similar function.

The semiconductor chip comprises an integrated circuit with a plurality of semiconductor functional regions 2 arranged on a common carrier 3. The semiconductor functional regions 2 are arranged aligned in a lattice-type grid on the carrier 3. The semiconductor functional regions 2 comprise series-connected operational semiconductor functional regions 20.

In addition, connectable semiconductor functional regions 21, 22, 23 are provided. The first connectable semiconductor functional region 21 has a first and a second terminal 211, 212. The second connectable semiconductor functional region 22 has a third and a fourth terminal 223, 224. The third connectable semiconductor functional region 23 has a fifth and a sixth terminal 235, 236.

A first region 41 of the contact structure connects the series-connected, operational semiconductor functional regions 20 with the first terminal 211 of the first semiconductor functional region 21. A second region 42 of the contact structure is electrically conductively connected to the second terminal 212 of the first semiconductor functional region 21 and the third terminal 223 on the second semiconductor functional region 22. A third region 43 of the contact structure is electrically conductively connected with the fourth terminal 224 on the second semiconductor functional region 22 and the fifth terminal 235 on the third semiconductor functional region 23. A fourth region 44 of the contact structure is electrically conductively connected to the sixth terminal 236 on the third semiconductor functional region 23. The fourth region 44 of the contact structure extends next to the connectable semiconductor functional regions 21, 22, 23 and is electrically conductively connected with the second contact 52.

A conductor structure comprises a first arm 81, which connects the fourth region 44 of the contact structure to the first region 41 the contact structure. A second arm 82 connects the fourth region 44 with the second region 42 of the contact structure. A third arm 83 connects the fourth region 44 of the contact structure with the third region 43 of the contact structure. The fourth region of the contact structure extending next to the connectable semiconductor functional regions 21, 22, 23 and the arms 81, 82, 83 have a comb-shaped structure.

The first connectable semiconductor functional region 21 is short-circuited by a branch extending from the first terminal 211 via the first region 41, the first arm 81, the fourth region 44, the second arm 82 and the second region 42 to the second terminal 212. The second connectable semiconductor functional region 22 is short-circuited by a branch extending from the third terminal 223 via the second region 42, the second arm 82, the fourth region 44, the third arm and the third region 43 to the fourth terminal 224. The third connectable semiconductor functional region 23 is short-circuited by a branch extending from the fifth terminal 235 via the third region 43, the third arm 83 and the fourth region 44 to the sixth terminal 236.

On application of a supply voltage to the contacts 51, 52, a voltage drop occurs across the operational semiconductor functional regions 20. The connectable semiconductor functional regions 21, 22, 23 are short-circuited, such that no or an infinitesimal voltage drop occurs across them.

Prior to disconnection of the conductor structure, the total forward voltage depends solely on the operational, series-connected semiconductor functional regions 20. Disconnection of the arms 81, 82, 83 allows adaptation of the total forward voltage to the predetermined supply voltage in a fabrication step, for example, the final fabrication step.

The first connectable semiconductor functional region 21 is activated when the first arm 81 is disconnected, such that the short circuit is eliminated. In this way, the fourth region 44 of the contact structure is electrically isolated from the first region 41. In FIG. 1, a possible disconnection point 61 is indicated, at which the first arm 81 may be disconnected. A suitable disconnection point isolates the first terminal 211 electrically from the second terminal 212 and from the fourth region 44 of the contact structure, such that on application of the supply voltage a voltage drop occurs across the first semiconductor functional region 21.

Disconnection of the contact structure may proceed by laser ablation of a part thereof. Alternatively, disconnection may proceed lithographically. After application of a mask which leaves the region to be interrupted uncovered, it is feasible to remove the region of the conductor structure which has been left uncovered, such that the arm 81 is disconnected.

In addition to the first semiconductor functional region 21, the second semiconductor functional region 22 may be activated, if the second arm 82 is also disconnected in such a way that the short circuit of the second semiconductor functional region 22 is eliminated. To this end, the second region 42 of the contact structure is electrically isolated from the fourth region 44. FIG. 2 identifies an example of a disconnection point 62. A suitable disconnection point isolates the third terminal 223 electrically from the second terminal 224 and from the fourth region 44 of the contact structure, such that on application of the supply voltage a voltage drop occurs across the second semiconductor functional region 22.

In addition to the first and second semiconductor functional regions 21, 22, the third semiconductor functional region 23 may be activated, if the third arm 83 is also disconnected in such a way that the short circuit of the third semiconductor functional region 23 is eliminated. To this end, the fourth region 44 of the contact structure is electrically isolated from the third region 43. FIG. 1 identifies an example of a disconnection point 63.

FIG. 2 shows an example of an arrangement in which up to three semiconductor functional regions may be connected to the already operational semiconductor functional regions 20. The circuit arrangement is cascadable by further connectable semiconductor functional regions.

Disconnection of the arms 81, 82, 83 allows the semiconductor chip to be adapted to the predetermined supply voltage. The total forward voltage of the semiconductor functional regions is detected and the contact structure is disconnected such that the difference between a total forward voltage and the predetermined supply voltage is reduced. If the total forward voltage is less than the supply voltage by roughly the forward voltage of a semiconductor functional region, the contact structure is disconnected, such that a connectable semiconductor functional region is activated. If the total forward voltage is less than the supply voltage by roughly a multiple of the forward voltage of a semiconductor functional region, the contact structure is disconnected, such that a number of connectable semiconductor functional regions corresponding to the multiple is activated.

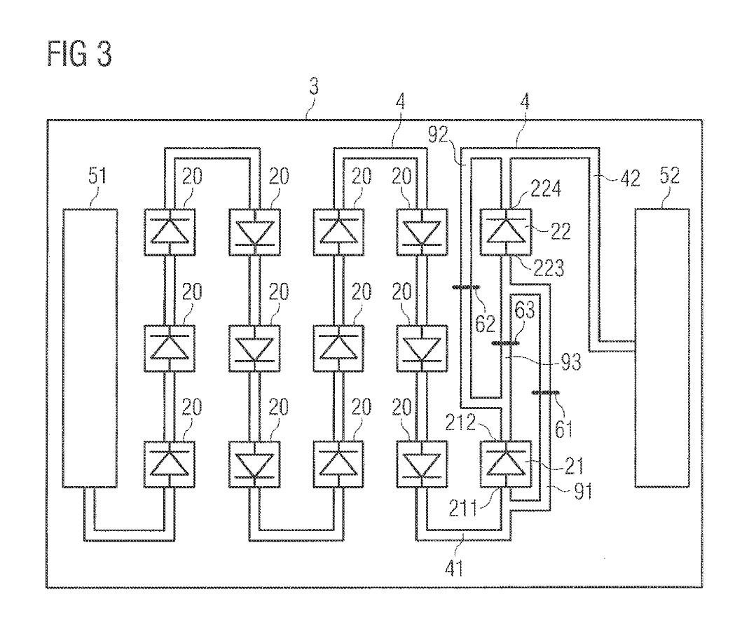

FIG. 3 is a schematic representation of a further exemplary embodiment of the arrangement of a contact structure for an optoelectronic semiconductor chip with a plurality of semiconductor functional regions.

The semiconductor functional regions 2 are arranged aligned in a lattice-type grid on the carrier 3. The semiconductor functional regions comprise series-connected operational semiconductor functional regions 20. An arrangement with a first and a second connectable semiconductor functional region 21, 22 is arranged downstream thereof. The first connectable semiconductor functional region 21 has a first and a second terminal 211, 212. The second connectable semiconductor functional region 22 has a third and a fourth terminal 223, 224.

A first region 41 of the contact structure connects the operational semiconductor functional regions 20 and the first terminal 211 of the first connectable semiconductor functional region 21. A second region 42 of the contact structure connects the second contact 52 and the fourth terminal 224 on the second connectable semiconductor functional region 22. The disconnectable conductor structure comprises first, second and third arms 91, 92, 93. The second terminal 212 on the first semiconductor functional region 21 is connected via a third arm 93 with the third terminal 223 on the second semiconductor functional region 22. A first arm 91 connects the first region 41 of the contact structure with the third arm 93. Thus a first short-circuiting branch extends from the first terminal 211, via the first region 41, the first arm 91 and the third arm 93 to the second terminal 212. A second arm 92 connects the third arm 93 with the second region 42. Thus a second branch extends from the third terminal 223, via the third and second arm 93, 92, the second region 42 to the fourth terminal 224. The first branch short-circuits the first semiconductor functional region 21. The second branch short-circuits the second semiconductor functional region 22.

In the above-described arrangement the first connectable semiconductor functional region 21 or second connectable semiconductor functional region 22 is activatable by disconnection of the branches. Alternatively, the two connectable semiconductor functional regions 21, 22 are activatable, such that these semiconductor functional regions are series-connected, or such that they are connected in parallel.

If just the first arm 91 is disconnected, the first connectable semiconductor functional region 21 is no longer short-circuited. The second semiconductor functional region 22 does, however, remain short-circuited. If just the second arm 92 is disconnected, the second connectable semiconductor functional region 22 is no longer short-circuited. The first semiconductor functional region 21 does, however, remain short-circuited.

By disconnecting the second and third arms 92, 93, both connectable semiconductor functional regions 21, 22 are activated, such that they are series-connected, since the current may flow via the third arm 93 from the first to the second semiconductor functional regions 21, 22.

By disconnecting the third arm 93 between the second and third terminals 92, 93, the first and second semiconductor functional regions 21, 22 are connected in parallel. By means of the first branch, the first terminal 211 on the first semiconductor functional region and the third terminal 223 on the second semiconductor functional region 22 are at the same potential. By means of the second branch, the second terminal 212 on the first semiconductor functional region and the fourth terminal 224 on the second semiconductor functional region 22 are at one potential. On application of the supply voltage, a voltage is applied across the two semiconductor functional regions 21, 22, such that electromagnetic radiation is emitted. Exemplary disconnection points are indicated by reference signs 61, 62, 63.

In the initial state, none of the arms 91, 92, 93 are disconnected. The total forward voltage depends solely on the forward voltages of the operational semiconductor functional regions 20, since the connectable semiconductor functional regions 21, 22 are short-circuited.

To activate the first connectable semiconductor functional region 21, the first arm 91 is disconnected for example at point 61. In this way, the first connectable semiconductor functional region 21 is no longer short-circuited and is now operational. The total forward voltage is increased by the forward voltage of the first connectable semiconductor functional region 21. Alternatively, just the second connectable semiconductor functional region 22 may also be transferred into an operational state by disconnecting the second arm 92, for example, at point 62. The total forward voltage is increased by the forward voltage of the second connectable semiconductor functional region 22.

To transfer the two connectable semiconductor functional regions 21, 22 into an operational state, the first and second arms 91, 92 are disconnected. The total forward voltage is increased by the forward voltages of the connected semiconductor functional regions.

Alternatively, just the third arm 93 may be disconnected, such that the two semiconductor functional regions are activated, but are connected in parallel. The total forward voltage is increased merely by the forward voltage drop which occurs at the parallel connection of the first and second semiconductor functional regions 21, 22, which is less than in the case of a series connection of the two.

By selecting between series and parallel connection of the connectable semiconductor functional regions 21, 22, the forward voltage is variable, without however having to do without the radiation emission of one of the semiconductor functional regions 21, 22. The forward voltage of the overall component may thus be adjusted, without active areas being lost. In this case, the light from the two parallel-connected semiconductor functional regions 21, 22 is even brighter at a lower current density, due to better pixel efficiency, than the light of a remaining pixel in the preceding exemplary embodiment.

In addition, the above-described adaptation in the case of series-connected multi-pixel LEDs may also be used to improve the yield of large-area and thus high-output LEDs. If numerous pixels are provided on the LED chip and a defect, for example, a short circuit, is present on one of the pixels, this pixel will not give light and also will not contribute to the total forward voltage. Through this adaptation, a replacement pixel may be connected, which assumes the light flux and voltage share of the failed pixel. For the first time, it is now possible to make large-area LED chips, which are larger than 2 square millimeters and have a maximum fabrication yield and tight specifications.

It should be noted that the above-described arrangement may be combined with parallel-connected semiconductor functional regions as described below.

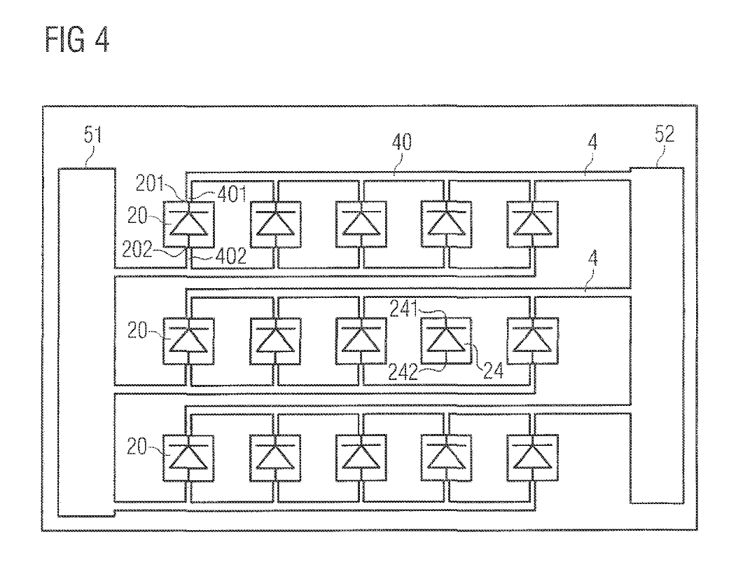

FIG. 4 shows such an arrangement with a plurality of semiconductor functional regions 20, which are arranged aligned in a grid. The semiconductor functional regions 20 each have a first and a second terminal 201, 202. In this exemplary embodiment, one of the semiconductor functional regions 24 is characterized as defective, for example, because it does not comply with a predetermined parameter or is not functional.

A contact structure 4 comprises contacts 51, 52 and linear, elongate regions 40 extending between the semiconductor functional regions 20. Above a row of semiconductor functional regions 20 there extends in each case an elongate region 40, for example, a conductor track, which is connected with one of the contacts 51, 52. Below a row there extends in each case an elongate region 40, which is connected with the other one of the contacts 51, 52. The first terminals 201 of the semiconductor functional region 20 are connected via first arms 401 with the linear regions 40, which are connected with the second contact 52. The second terminals 202 are connected with the linear regions 40 via second arms 402, which are connected with the first contact 51, such that the semiconductor functional regions 20 are connected in parallel.

Provision is made, however, for no conductive connection to be provided between some terminals and the adjacent linear region 40, such that, for example, the semiconductor functional region 24 characterized as defective is purposefully isolated from the conductor tracks and thus permanently deactivated. In the case of a defective semiconductor functional region 24, no conductive connection is provided between the first and second terminals 241, 242 thereof and the in each case adjacent linear regions 40 of the contact structure. The chip is thus functional, although individual pixels 24 have been purposefully deactivated, in that an isolation structure is present between the terminals 241, 242 thereof and the other regions of the contact structure 4.

Purposeful switching off of pixels 24 characterized as defective allows the production of large-area chips with a plurality of semiconductor functional regions.

Semiconductor functional regions 24 which have been characterized as defective may be deactivated in one of the final production steps. Switching off may take place after the production process, i.e. by the disconnection of contact bridges provided, or during the fabrication process, for example by purposeful isolation of contact points.

The chip may, for example, be of self-correcting construction. In the case of a short circuit in a pixel the electrical connections to this pixel are cut by the high current flow occurring as a result. This effect is similar to the effect of a safety fuse.

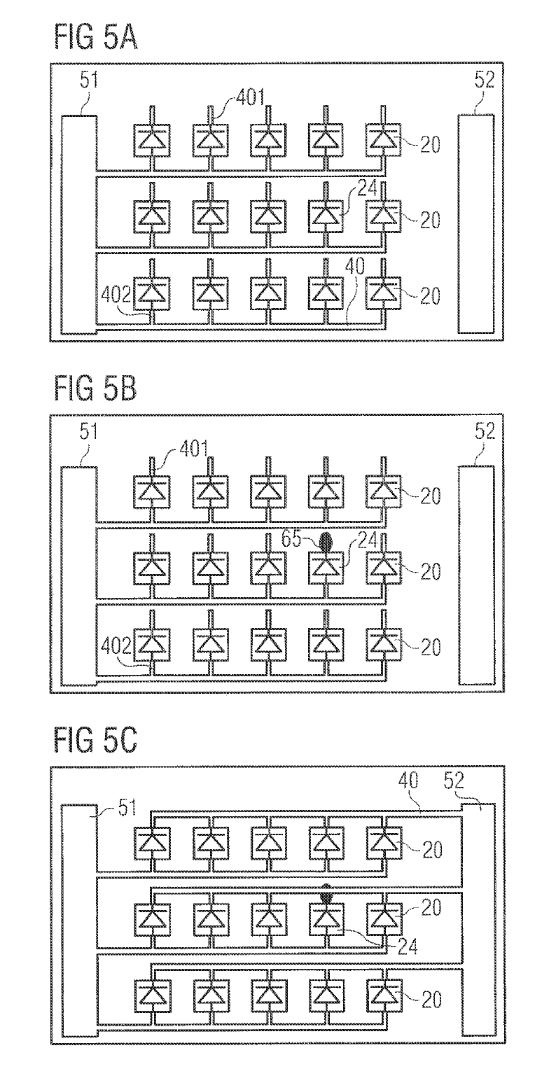

FIGS. 5A to 5C show purposeful switch-off of semiconductor functional regions during fabrication. First of all, after formation of the semiconductor functional regions the latter are detected with regard to possible defects. Detection may proceed, for example, by means of visual inspection or by the application of a voltage by prober needles. This step may proceed in the wafer composite, if no contact structure has as yet been applied. Alternatively, the step may take place if just part of the contact structure has been applied.

FIG. 5A shows an intermediate product, in which the detection step may take place. The intermediate product comprises semiconductor functional regions 20, 24 and part of the contact structure. Arms 401, 402, which contact the terminals 201, 202 of the semiconductor functional regions 20, and linear regions 40, which are connected with the first contact 51 and the arms 402 on the second terminals 202, have already been provided.

An insulating material 65 is then applied to the first arm 401 of the semiconductor functional region 24 which has been classified as defective. This step is illustrated in FIG. 5B. It is also feasible for a plurality of semiconductor functional regions to be classified as defective.

The linear regions 40 are then applied, which connect the first arms 401 and are in turn connected to the second contact 52, as shown in FIG. 5C. In the case of the arms to which the insulating material 65 has been applied, no electrically conductive connection arises between the first terminal 241 of the semiconductor functional regions 24 and the linear region 40 of the contact structure, such that this semiconductor region 24 is not operational. Purposeful switching off of this pixel 24 largely does not affect the functioning of the others, which allows a high fabrication yield. It is also feasible for an insulating material 65 to be provided between the second arm on the defective semiconductor functional region 24 and the linear region 40.

The above-described purposeful disconnection of semiconductor functional regions classified as defective may be combined with the connectable semiconductor functional regions in a circuit arrangement.

It is feasible for both connected or connectable semiconductor functional regions and disconnectable or disconnected semiconductor functional regions to be provided in one circuit arrangement.

It should be noted that the features of the exemplary embodiments may be combined.

The invention is not restricted by the description given with reference to the exemplary embodiments. Rather, the invention encompasses any novel feature and any combination of features, including in particular any combination of features in the claims, even if this feature or this combination is not itself explicitly indicated in the claims or exemplary embodiments.

1-14. (canceled)

15. An optoelectronic semiconductor chip comprising:
a first semiconductor functional region with a first terminal and a second terminal;
a contact structure for electrically contacting the optoelectronic semiconductor chip,
wherein the contact structure is electrically conductively connected to the first semiconductor functional region, the contact structure comprising a disconnectable conductor structure;
wherein an operating current path is established via the first terminal and the second terminal when the conductor structure is not disconnected, the path being interrupted when the conductor structure is disconnected; or
wherein an operating current path is established via the first terminal and the second terminal when the conductor structure is disconnected, wherein the conductor structure connects the first terminal to the second terminal and short circuits the first semiconductor functional region when the conductor structure is not disconnected.

16. The optoelectronic semiconductor chip according to claim 15, wherein an operating current path is established via the first terminal and the second terminal when the conductor structure is not disconnected, the path being interrupted when the conductor structure is disconnected.

17. The optoelectronic semiconductor chip according to claim 15, wherein an operating current path is established via the first terminal and the second terminal when the conductor structure is disconnected, wherein the conductor connects the first terminal to the second terminal thereby short circuiting the first semiconductor functional region when the conductor structure is not disconnected.

18. The optoelectronic semiconductor chip according to claim 15, wherein that the semiconductor functional region comprises an active zone configured to generate or receive radiation.

19. The optoelectronic semiconductor chip according to claim 15, wherein the conductor structure is connected in parallel with the first semiconductor functional region.

20. The optoelectronic semiconductor chip according to claim 15, further comprising a second semiconductor functional region is provided with a third and a fourth terminal, wherein a connection region of the contact structure connects the second and the third terminals and wherein the conductor structure comprises a first branch extending between the first terminal and the connection region, the first branch being disconnectable or disconnected, wherein the conductor structure further comprises a second branch extending between the connection region and the fourth terminal, the second branch being disconnectable or disconnected.

21. The optoelectronic semiconductor chip according to claim 20, wherein the first branch and the second branch have a common region that is separable or separated.

22. The optoelectronic semiconductor chip according to claim 15, further comprising a second semiconductor functional region is provided with a third terminal and a fourth terminal, wherein the conductor structure comprises a first branch extending between the first and third terminals, the first branch being disconnectable or disconnected, the conductor structure also comprising a second branch extending between the second and third terminals and a third branch extending between the second and third terminal, both the second branch and the third branch being disconnectable or disconnected.

23. The optoelectronic semiconductor chip according to claim 22, wherein either none of the branches is disconnected, or just the third branch is disconnected, or just the first and/or the second branch is/are disconnected.

24. The optoelectronic semiconductor chip according to claim 15, wherein the chip includes a plurality of series-connected semiconductor functional regions that are operational, the first semiconductor functional region being one of the series-connected semiconductor functional regions.

25. A method for adapting a contact structure for electrically contacting an optoelectronic semiconductor chip with a first semiconductor functional region with a first terminal and a second terminal and also with a contact structure for electrically contacting the optoelectronic semiconductor chip, the contact structure being electrically conductively connected with the first semiconductor functional region, wherein the contact structure comprises a disconnectable conductor structure, wherein the method comprises:
disconnecting an operating current path that is established across the first terminal of the semiconductor functional region and the second terminal, such that the operating current path is interrupted; or
disconnecting the conductor structure that connects the first terminal with the second terminal and short-circuits the semiconductor functional region, such that if the conductor structure is disconnected an operating current path is established across the first terminal of the semiconductor functional region and the second terminal.

26. The method according to claim 25, wherein the method comprises disconnecting the operating current path that is established across the first terminal of the semiconductor functional region and the second terminal, such that the operating current path is interrupted.

27. The method according to claim 25, wherein the method comprises disconnecting the conductor structure that connects the first terminal with the second terminal and short-circuits the semiconductor functional region, such that if the conductor structure is disconnected an operating current path is established across the first terminal of the semiconductor functional region and the second terminal.

28. The method according to claim 25, wherein the optoelectronic semiconductor chip further comprises a second semiconductor functional region provided with a third and a fourth terminal, wherein a connection region of the contact structure connects the second and third terminals and wherein the conductor structure comprises a first branch electrically connecting the first terminal and the connection region and a second branch electrically connecting the connection region and the fourth terminal;
wherein the first branch is disconnected; or
wherein the second branch is disconnected; or
wherein the first and second branches are disconnected.

29. The method according to claim 25, wherein the optoelectronic semiconductor chip further comprises a second semiconductor functional region provided with a third and a fourth terminal, wherein the conductor structure comprises a first branch electrically connecting the first and third terminals and a second branch electrically connecting the second and fourth terminals and a third branch electrically connecting the second and third terminals, wherein:
the third branch is disconnected; or
the first branch is disconnected; or
the second branch is disconnected; or
the first and second branches are disconnected.

30. The method according to claim 25, wherein a total forward voltage of a plurality of semiconductor functional regions is detected and the conductor structure is disconnected such that the difference between the total forward voltage and a predetermined supply voltage is reduced.

31. The method according to claim 27, wherein disconnecting the conductor structure comprises performing laser ablation of a part of the conductor structure.

32. The method according to claim 26, wherein disconnecting the operating current path comprises disconnecting the operating current path lithographically.

33. The method according to claim 27, wherein disconnecting the conductor structure comprises disconnecting the conductor structure lithographically.

34. An optoelectronic semiconductor chip comprising:
a first semiconductor functional region with a first terminal and a second terminal;
a contract structure for electrically contacting the optoelectronic semiconductor chip, the contact structure being electrically conductively connected to the first semiconductor functional region, the contact structure comprising a disconnectable conductor structure; and
a plurality of series-connected semiconductor functional regions that are operational.
